(19) United States
(12) Patent Application Publication
(10) Pub. No.: US 2013/0057153 A1
(43) Pub. Date: Mar. 7, 2013

(54) LIGHT-EMITTING DIODE LAMP

(71) Applicants: Sung-jin KIM, Suwon-si (KR); Byung-kwan SONG, Bucheon-si (KR)

(72) Inventors: Sung-jin KIM, Suwon-si (KR); Byung-kwan SONG, Bucheon-si (KR)

(73) Assignee: SAMSUNG ELECTRONICS CO., LTD., Suwon-si (KR)

(21) Appl. No.: 13/601,104

(22) Filed: Aug. 31, 2012

(30) Foreign Application Priority Data
Sep. 2, 2011 (KR) 10-2011-0089209

(51) Int. Cl. H01L 33/64

(52) U.S. Cl. 315/113

(57) ABSTRACT

A light-emitting diode lamp is provided. The light-emitting diode lamp includes a light-emitting diode package that includes a light-emitting diode and a circuit substrate on which the light-emitting diode is mounted; a power supply unit that supplies power to the light-emitting diode; a heat radiation member that includes a mounting unit on which the light-emitting diode package is mounted and a cylindrical unit extending from the mounting unit and surrounding the power supply unit to discharge heat generated by the light-emitting diode package; and a heat radiation plastic that surrounds an outer surface of the cylindrical unit.

### CROSS-REFERENCE TO RELATED APPLICATION

This application claims priority from Korean Patent Application No. 10-2011-0089209, filed on Sep. 2, 2011 in the Korean Intellectual Property Office, the disclosure of which is incorporated by reference herein in its entirety.

### BACKGROUND

1. Field

The present disclosure relates to light-emitting diode lamps, and more particularly, to small light-emitting diode lamps having a small non-insulation type power supply unit.

2. Description of the Related Art

Light-emitting diodes (LEDs) are semiconductor devices that realize various light colors by configuring a light source having a PN junction of compound semiconductors. LEDs have a long lifetime, may be miniaturized and may be driven at a low voltage due to high directionality. Also, LEDs are strong against impact and vibration, do not require a preheating time or a complicated driving arrangement, and may be packaged in various types. Accordingly, LEDs may be applied for various purposes.

An LED lamp uses an LED as a light source and has a conventional lamp shape, such as an incandescent lamp, a fluorescent lamp, or a halogen lamp.

When a conventional lamp, such as an incandescent lamp, a fluorescent lamp, or a halogen lamp, is replaced by an LED lamp, high efficiency and long lifetime characteristics are may be realized through securing a heat radiation characteristic. With a low power output, a sufficient heat radiation characteristic (i.e., sufficient heat dissipation) may be realized within a limited size and type. However, as the output increases, it is not easy to secure a sufficient heat radiation characteristic within a limited size and type.

### SUMMARY

One or more exemplary embodiments provide light-emitting diode lamps having an improved structure of a heat radiation member to realize a light-emitting diode lamp having a non-insulation type power supply unit.

According to an aspect of an exemplary embodiment, there is provided a light-emitting diode lamp including a light-emitting diode package that includes at least one light-emitting diode and a circuit substrate on which the light-emitting diode is mounted; a power supply unit that supplies power to the light-emitting diode; a heat radiation member that includes a mounting unit on which the light-emitting diode package is mounted and a cylindrical unit extending from the mounting unit and surrounding the power supply unit to discharge heat generated by the light-emitting diode package; and a heat radiation plastic that surrounds an outer surface of the cylindrical unit.

The heat radiation plastic may be formed of a polyphenylene sulfide group material.

The heat radiation plastic may include a ceramic filler in the polyphenylene sulfide group material.

The ceramic filler may be formed of at least one selected from the group consisting of alumina, MgO, BN, and AlN.

The heat radiation plastic may include the ceramic filler in a range from about 10 wt. % to about 30 wt. % of the heat radiation plastic.

The mounting unit and the cylindrical unit of the heat radiation member may be formed as one body.

The heat radiation member may be formed of aluminum.

The heat radiation plastic may be a member formed by insert-injection molding.

Heat radiation fins may be formed on an external circumference of the heat radiation plastic.

The light-emitting diode lamp may further include a socket unit that supplies external power to the power supply unit; an insulating member that is positioned between the socket unit and the heat radiation member and surrounds the power supply unit; and a lamp cover that covers the light-emitting diode package and is attached to the heat radiation member.

The power supply unit may be a non-insulation type power supply unit including a transformation circuit without a transformer.

### BRIEF DESCRIPTION OF THE DRAWINGS

These above and/or other aspects will become apparent and more readily appreciated from the following description of exemplary embodiments, taken in conjunction with the accompanying drawings in which:

FIG. 1 is an exploded perspective view of a light-emitting diode lamp according to an exemplary embodiment;

FIG. 2 is a perspective view of a light-emitting diode lamp according to an exemplary embodiment;

FIG. 3 is a perspective view of a heat radiation member according to an exemplary embodiment; and

FIG. 4 is a perspective view showing a combination of a heat radiation member and a heat radiation plastic according to an exemplary embodiment.

### DETAILED DESCRIPTION

Reference will now be made in detail to exemplary embodiments, examples of which are illustrated in the accompanying drawings. In the drawings, thicknesses of layers or regions are exaggerated for clarity. Like reference numerals refer to like elements throughout and thus descriptions thereof will be omitted.

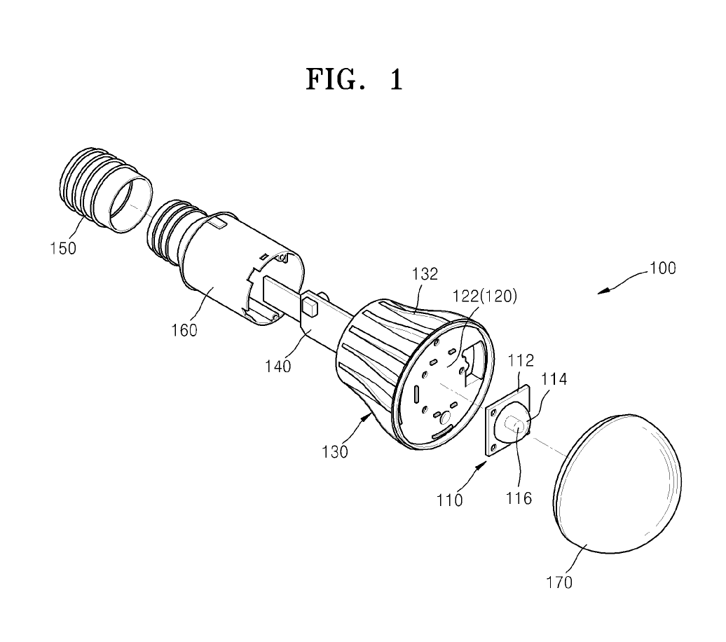

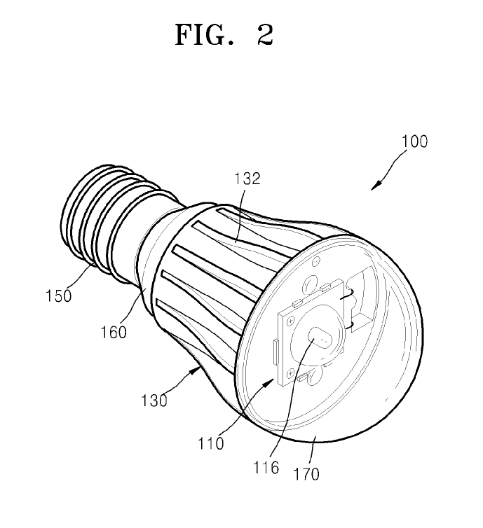

FIG. 1 is an exploded perspective view of a light-emitting diode lamp 100 according to an exemplary embodiment. FIG. 2 is a perspective view of the light-emitting diode lamp 100 according to an exemplary embodiment. The light-emitting diode lamp 100 depicted in FIGS. 1 and 2 is an incandescent lamp type.

Referring to FIGS. 1 and 2, the light-emitting diode lamp 100 includes a heat radiation member 120 that provides a mounting unit 122 on which a light-emitting diode package 110 is mounted, a power supply unit 140 that is surrounded by the heat radiation member 120 and supplies power to the light-emitting diode package 110, and a lamp cover 170.

The light-emitting diode package 110 may include a light-emitting diode 116, a circuit substrate 112 on which the light-emitting diode 116 is mounted, and a lens unit 114 that covers the light-emitting diode. The light-emitting diode 116 may include a plurality of light-emitting diodes, and the light-emitting diodes may be arranged in series, parallel type, or a combination thereof. A transparent filler material that includes a phosphor may be filled between the circuit substrate 112 and the lens unit 114. The light-emitting diode 116 may be a white light-emitting diode (LED) emitting white light. For example, the light-emitting diode 116 may be a blue LED, and the phosphor may be yellow color. The transparent filler material may be, for example, an epoxy resin.

Also, the light-emitting diode 116 may be mounted on the circuit substrate 112 as an LED chip type coated with a phosphor by a wire bonding method. Also, the light-emitting diode 116 may be mounted on the circuit substrate 112 as an LED chip type coated with a phosphor by a flip-chip bonding method. The circuit substrate 112 may be a metal substrate or have a metal core for increasing a heat radiation characteristic.

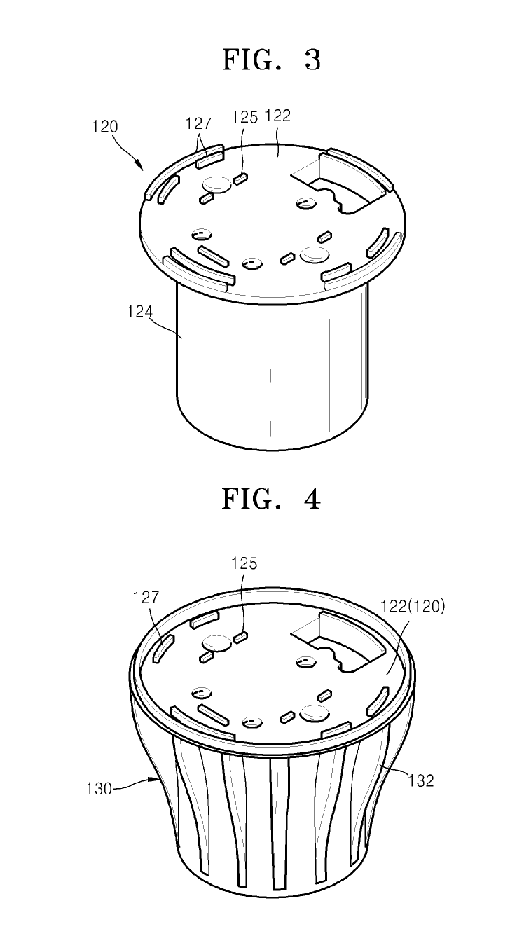

The heat radiation member 120 includes the mounting unit 122 on which the light-emitting diode package 110 is mounted and a cylindrical unit 124 (refer to FIG. 3) extending in a direction opposite to the light-emitting diode package 110 from the mounting unit 122. The mounting unit 122 and the cylindrical unit 124 may be formed as one body. The cylindrical unit 124 is formed to surround the power supply unit 140. The heat radiation member 120 is formed to discharge heat generated by the light-emitting diode 116 to the outside, and may be formed of a metal material having a high thermal conductivity, such as aluminum. The heat radiation member 120 is also referred to as a heat sink. An outer circumference of the heat radiation member 120 is surrounded by a heat radiation plastic 130. The heat radiation plastic 130 is exposed to air and includes a heat radiation fin 132 having a wrinkle shape to increase a heat radiation area. The cylindrical unit 124 is described below.

The power supply unit 140 electrically connects a socket unit 150 that satisfies the specification of an incandescent lamp to the circuit substrate 112. The power supply unit 140 includes a driving circuit for driving the light-emitting diode 116 using external power supplied through the socket unit 150.

The light-emitting diode lamp 100 may include an insulating member 160 that is disposed between the heat radiation member 120 and the power supply unit 140 to insulate the cylindrical unit 124 of the heat radiation member 120 from the power supply unit 140. The insulating member 160 has a shape surrounding the power supply unit 140, and the cylindrical unit 124 surrounds the insulating member 160. The insulating member 160 may extend inside the socket unit 150. The insulating member 160 is also referred to as a power supply unit housing. The insulating member 160 may be formed of polybutylene terephthalate (PBT) resin.

The light-emitting diode lamp 100 according to an exemplary embodiment may be a small low-cost type lamp, for example, a lamp of 5 W or below. When a small light-emitting diode lamp is manufactured, in order to design a withstanding voltage in the power supply unit 140, it may be difficult to use a related art insulation method, for example, electrical insulation by a transformer. A transformer has a large volume and is expensive, and thus, it is difficult to use the transformer in a small low-cost light-emitting diode lamp. In the power supply unit 140, a transformation circuit is formed by using an inductor without including a transformer. Also, an additional insulation method is not included. This kind of insulation method is referred to as a non-insulation type method. When an over-current greater than a predetermined level flows in the non-insulation type power supply unit 140, the current may flow to the heat radiation member 120 due to a spark. Accordingly, a hand-grip region of the cylindrical unit 124 of the heat radiation member 120 is insulated. In the current exemplary embodiment, the heat radiation plastic 130, which is an insulating material, is formed on the cylindrical unit 124. That is, the heat radiation plastic 130 dissipates heat, and also prevents an electric shock that may be caused by an over-current.

The heat radiation plastic 130 may be formed of a polyphenylene sulfide group material. In order to increase the thermal conductivity of the heat radiation plastic 130, a ceramic filler may further be included in the polyphenylene sulfide group material. The ceramic filler may include Al₂O₃, MgO, BN, or AlN. The ceramic filler may be included in a range from about 10 wt. % to about 30 wt. % in the heat radiation plastic 130. If the ceramic filler is less than 10 wt. %, the thermal conductivity may not be high. If the ceramic filler is greater than 30 wt. %, a surface roughness of the heat radiation plastic 130 may be increased.

The heat radiation plastic 130 may be formed of polycarbonate or polyamide, besides the polyphenylene sulfide group material.

FIG. 3 is a perspective view of the heat radiation member 120 according to an exemplary embodiment, and FIG. 4 is a perspective view showing a combination of the heat radiation member 120 and the heat radiation plastic 130.

Referring to FIG. 3, the heat radiation member 120 is an insert core formed of aluminum. The heat radiation member 120 may be formed by using a die-casting method. As described above, the heat radiation member 120 includes the mounting unit 122 and the cylindrical unit 124. Guides 125 that define the location of the light-emitting diode package 110 are formed on the mounting unit 122. The guides 125 define the location of the light-emitting diode package 110 when the light-emitting diode package 110 is bolt-attached to the mounting unit 122. Guides 127 are used for attaching the lamp cover 170 described below.

In FIG. 4, the heat radiation plastic 130 is formed on an outer circumference of the heat radiation member 120. The heat radiation plastic 130 is formed by using an insert-injection molding method. The heat radiation fins 132 are formed on an outer circumference of the heat radiation plastic 130. The heat radiation fins 132 may increase a heat radiation area and improve a grip feeling. Since an external circumference of the heat radiation member 120 is surrounded by the heat radiation plastic 130 when an insert-injection molding is performed, a failure rate with respect to the outer circumference of the heat radiation member 120 may be mitigated, and accordingly, the yield of the heat radiation member 120 may be increased.

The lamp cover 170 is a dome type transparent cover, has an empty inner side, and covers the light-emitting diode package 110 by attachment to the heat radiation member 120. The lamp cover 170 performs a bulb shape maintaining function and a light-emitting diode protection function. Also, the lamp cover 170 may have a structure for diffusing light.

The lamp cover 170 may be attached to the mounting unit 122 of the heat radiation member 120 by using a snap-fit method. The method of attaching the lamp cover 170 to the heat radiation member 120 is not limited thereto. For example, other methods such as, using combining grooves, may be used.

Heat generated in a process of driving the light-emitting diode 116 is transmitted to the heat radiation member 120 and the heat radiation plastic 130 through the circuit substrate 112, and is discharged to the air through the external circumference of the heat radiation plastic 130 that is in contact with the air.

In order for a small light-emitting diode lamp to realize a high efficiency characteristic and a long lifetime characteristic, a sufficient heat radiation performance is provided within a limited size and shape.

An effective heat radiation area is substantially limited to surface areas of the cylindrical unit 124 of the heat radiation member 120 and the heat radiation plastic 130. In FIG. 4, the heat radiation fins 132 are formed to increase a heat radiation area. However, the manner of increasing heat radiation area is not limited thereto. For example, the thermal conductivity of the light-emitting diode lamp 100 may further be effectively increased by forming heat radiation fins on the cylindrical unit 124 of the heat radiation member 120 which is an insert-core.

According to the exemplary embodiment, an electrical shock that may cause by an over current is prevented and heat radiation efficiency is increased by forming a heat radiation plastic that is designed to have a high thermal conductivity on an outer circumference of a heat radiation member. An insulation of a power supply unit may be circularly configured. Therefore, a small and low-cost light-emitting diode lamp may be realized.

While exemplary embodiments have been particularly shown and described, it will be understood by those of ordinary skill in the art that various changes in form and details may be made therein without departing from the spirit and scope of the inventive concept as defined by the appended claims.

What is claimed is:

1. A light-emitting diode lamp comprising:
a light-emitting diode package that comprises at least one light-emitting diode and a circuit substrate on which the light-emitting diode is mounted;
a power supply unit that supplies power to the light-emitting diode;
a heat radiation member that comprises a mounting unit on which the light-emitting diode package is mounted, and a cylindrical unit extending from the mounting unit and surrounding the power supply unit to discharge heat generated by the light-emitting diode package; and
a heat radiation plastic that surrounds an outer surface of the cylindrical unit.

2. The light-emitting diode lamp of claim 1, wherein the heat radiation plastic is formed of a polyphenylene sulfide group material.

3. The light-emitting diode lamp of claim 2, wherein the heat radiation plastic includes a ceramic filler in the polyphenylene sulfide group material.

4. The light-emitting diode lamp of claim 3, wherein the ceramic filler is formed of at least one selected from the group consisting of alumina, MgO, BN, and AlN.

5. The light-emitting diode lamp of claim 4, wherein the heat radiation plastic includes the ceramic filler in a range from about 10 wt. % to about 30 wt. % of the heat radiation plastic.

6. The light-emitting diode lamp of claim 1, wherein the mounting unit and the cylindrical unit of the heat radiation member are formed as one body.

7. The light-emitting diode lamp of claim 6, wherein the heat radiation member is formed of aluminum.

8. The light-emitting diode lamp of claim 6, wherein the heat radiation plastic is a member formed by insert-injection molding.

9. The light-emitting diode lamp of claim 6, wherein the heat radiation plastic includes heat radiation fins on an external circumference thereof.

10. The light-emitting diode lamp of claim 1, further comprising:
a socket unit that supplies external power to the power supply unit;
an insulating member that is positioned between the socket unit and the heat radiation member and surrounds the power supply unit; and
a lamp cover that covers the light-emitting diode package and is attached to the heat radiation member.

11. The light-emitting diode lamp of claim 1, wherein the power supply unit is a non-insulation type power supply unit including a transformation circuit without a transformer.

12. A transformer-less light-emitting diode lamp comprising:
at least one light emitting diode;
a circuit substrate on which the at least one light emitting diode is mounted;
a power supply that supplies power to the at least one light-emitting diode;
a heat sink on which the circuit substrate is mounted, the heat sink surrounding at least a portion of the power supply; and
a heat radiation plastic that surrounds an outer surface of the heat sink,
wherein the heat sink transfers heat from the circuit substrate to the heat radiation plastic.

13. The transformer-less light-emitting diode lamp of claim 12, wherein the heat radiation plastic comprises a plurality of fins on an external circumference thereof.

14. The transformer-less light-emitting diode lamp of claim 12, wherein the heat radiation plastic is formed of a polyphenyle sulfide group metal.

15. The light-emitting diode lamp of claim 12, wherein the heat radiation plastic comprises a ceramic filler.

16. The light-emitting diode lamp of claim 15, wherein the ceramic filler is formed of alumina, MgO, BN, or AlN.

17. The light-emitting diode lamp of claim 15, wherein the heat radiation plastic includes the ceramic filler in a range from about 10 wt. % to about 30 wt. % of the heat radiation plastic.

18. The light-emitting diode lamp of claim 12, wherein the heat radiation plastic is insert-injection molded.

19. The light-emitting diode lamp of claim 12, wherein the heat sink is aluminum.

20. The light-emitting diode lamp of claim 12, further comprising:
a socket that supplies external power to the power supply;
an insulator that is positioned between the socket and the heat sink and surrounds the power supply; and
a lamp cover that covers the at least one light-emitting diode and is attached to the heat sink.
